(19) United States
(12) Patent Application Publication
(10) Pub. No.: US 2026/0266894 A1
(43) Pub. Date: Sep. 10, 2026

(54) TEST METHOD, TEST APPARATUS, AND TEST SYSTEM

(71) Applicant: KYOCERA DOCUMENT SOLUTIONS INC., Osaka (JP)

(72) Inventor: TETSUTAKA YABUTA, OSAKA (JP)

(21) Appl. No.: 19/546,447

(22) Filed: Feb. 23, 2026

(30) Foreign Application Priority Data
Mar. 5, 2025 (JP) 2025-034427

(51) Int. Cl. G01R 31/28

(52) U.S. Cl. CPC G01R 31/2834; G01R 31/2825

(57) ABSTRACT

A test method includes: by a control circuit of a test apparatus executing a test program, obtaining a configuration value and/or history information of a test target electronic device; recording the obtained configuration value and/or the obtained history information as backup data in a storage device; executing a test on the test target electronic device; and restoring the backup data in the test target electronic device after the test is executed.

### CROSS-REFERENCE TO RELATED PATENT APPLICATION

This application claims the benefit of Japanese Priority Patent Application JP 2025-034427 filed March 5, 2025, the entire contents of which are incorporated herein by reference.

### FIELD OF THE DISCLOSURE

The present disclosure relates to a test method, a test apparatus, and a test system that execute a test on an electronic device, such as an image forming device.

### BACKGROUND OF THE DISCLOSURE

Only a limited number of prototypes of an electronic device under development (e.g., an image forming device) can be assigned to each department to save the development cost. Therefore, involved developers share the prototypes of the electronic device under development assigned to each department.

When a test is executed on the electronic device under development, events such as changes in configuration values and registration of logs related to jobs caused by the test occur in the prototypes of the tested electronic device under development. In such a case, the configuration values of the prototypes of the electronic device under development that are shared among the developers may be changed to unintended values. This may cause problems, for example, in that the users (developers) cannot thereafter use the prototypes of the electronic device under development as they expect and the users (developers) cannot thereafter conduct tests as they expect due to unintended history registration.

Typically, an automatic test tool for verifying whether a changed implementation part(s) will affect other existing implementations is disclosed. However, impacts on an electronic device to be verified in verification with the automatic test tool and possible inconvenience in a scenario where the affected electronic device is thereafter used are not considered.

### SUMMARY OF THE DISCLOSURE

A test method according to an aspect of the present disclosure includes, by a control circuit of a test apparatus, executing a test program, obtaining a configuration value and/or history information of a test target electronic device. The test method further includes recording the obtained configuration value and/or the obtained history information as backup data in a storage device. The test method further includes executing a test on the test target electronic device. The test method further includes restoring the backup data in the test target electronic device after the test is executed.

A test apparatus according to an aspect of the present disclosure includes an obtaining unit, a backup unit, a test execution unit, and a restoring unit. The obtaining unit obtains a configuration value and/or history information of a test target electronic device. The backup unit records the obtained configuration value and/or the obtained history information as backup data in a storage device. The test execution unit executes a test on the test target electronic device. The restoring unit restores the backup data in the test target electronic device after the test is executed.

A test system according to an aspect of the present disclosure includes a test target electronic device and a test apparatus. The test apparatus includes an obtaining unit, a backup unit, a test execution unit, and a restoring unit. The obtaining unit obtains the configuration value and/or the history information of the test target electronic device. The backup unit records the obtained configuration value and/or the obtained history information as backup data in a storage device. The test execution unit executes a test on the test target electronic device. The restoring unit restores the backup data in the test target electronic device after the test is executed.

These and other objects, features and advantages of the present disclosure will become more apparent in light of the following detailed description of best mode embodiments thereof, as illustrated in the accompanying drawings.

### BRIEF DESCRIPTION OF THE DRAWINGS

FIG. 1 shows a test system that executes a test method according to an embodiment of the present disclosure.

FIG. 2 shows a hardware configuration of a test apparatus.

FIG. 3 shows a hardware configuration of an image forming device.

FIG. 4 shows a functional configuration of a test system.

FIG. 5 shows an operation sequence of the test system.

FIG. 6 shows an operation sequence of a test system according to another embodiment.

### DETAILED DESCRIPTION OF THE EXEMPLARY EMBODIMENTS

Hereinafter, embodiments of the present disclosure will be described with reference to the drawings.

### 1. Test System

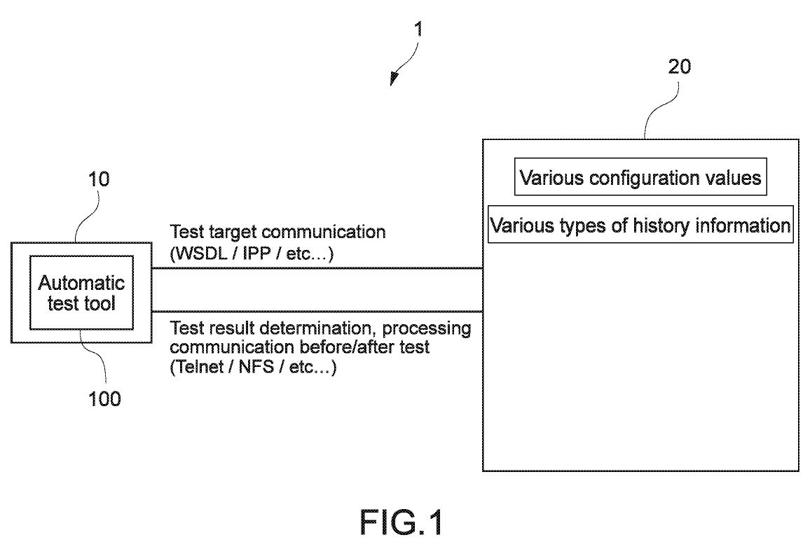

FIG. 1 shows a test system that executes a test method according to an embodiment of the present disclosure.

A test system 1 includes a test apparatus 10 and a test target electronic device 20. The test apparatus 10 is an information processing apparatus that executes a test program, such as a personal computer. For example, the test target electronic device 20 is an image forming device, such as a multifunction peripheral (MFP). The test apparatus 10 and the test target electronic device 20 are connected to be capable of communicating with each other in accordance with communication standards, such as WSDL or IPP. In the following description, it is assumed that the test target electronic device 20 is an image forming device.

### 2. Test Apparatus

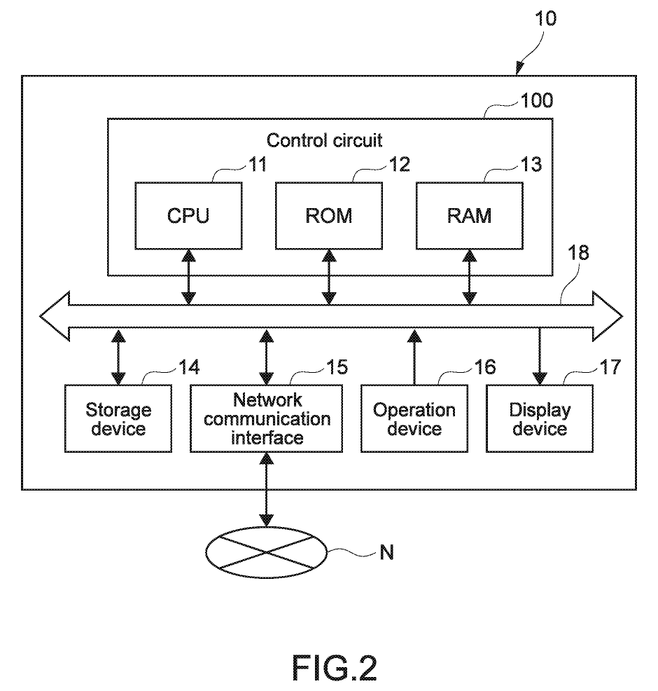

FIG. 2 shows a hardware configuration of the test apparatus.

The test apparatus 10 includes a central processing unit (CPU) 11, a read only memory (ROM) 12, a random access memory (RAM) 13, a high-volume nonvolatile storage device 14, such as a hard disk drive (HDD) or solid state drive (SSD), a network communication interface 15, an operation device 16, and a display device 17. The test apparatus 10 further includes a bus 18 that mutually connects them.

The CPU 11, the ROM 12, and the RAM 13 constitute a control circuit 100. The CPU 11 loads an information processing program stored in the ROM 12 to the RAM 13 and executes the loaded information processing program. The ROM 12 fixedly stores programs, data, and the like that are executed by the CPU 11. The ROM 12 is an example of a non-transitory computer-readable recording medium.

### 3. Hardware Configuration of Image Forming Device

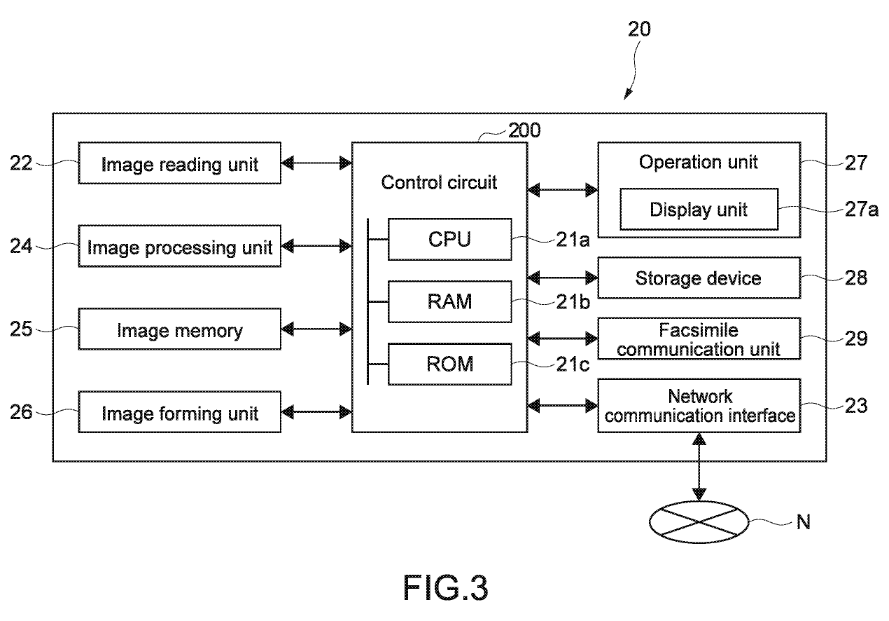

FIG. 3 shows a hardware configuration of the image forming device.

An image forming device 20 includes a control circuit 200 that constitutes a computer. The control circuit 200 is constituted by a central processing unit (CPU) 21a that is a processor, a random access memory (RAM) 22b, a read only memory (ROM) 22c that is a memory, a dedicated hardware circuit, and the like. The control circuit 200 serves to control general operations of the image forming device 20. The CPU 21a loads an information processing program stored in the ROM 22c to the RAM 22b and executes the loaded information processing program to execute operations in an operation flow to be described below and control display and operation inputs of a touch panel 27. The ROM 22c fixedly stores programs, data, and the like that are executed by the CPU 21a. The ROM 22c is an example of a non-transitory computer-readable recording medium.

The control circuit 200 is connected to an image reading unit 22 (image scanner), an image processing unit 24 (including graphics processing unit (GPU)), an image memory 25, an image forming unit 26 (printer), a touch panel (front panel) 27 that is an operation unit with a display unit 27a, a high-volume nonvolatile storage device 28, such as a hard disk drive (HDD) or solid state drive (SSD), a facsimile communication unit 29, and a network communication interface 23 (communication unit), for example. The control circuit 200 performs operation control on the respective units connected thereto and transmits/receives signals or data to/from the respective units. The operation unit of the touch panel 27 is a form of the input device. An audio input device with a microphone may be provided as the input device.

### 4. Functional Configuration of Test System

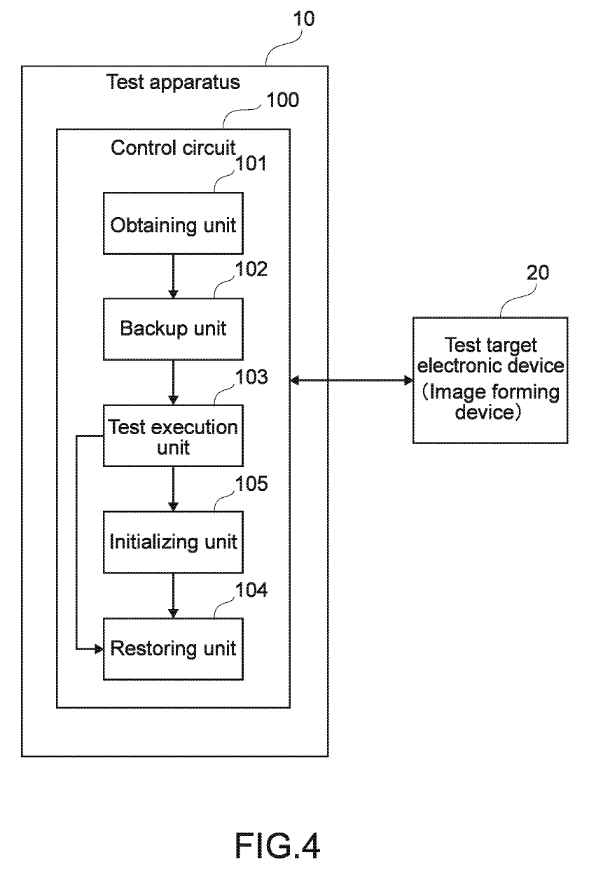

FIG. 4 shows a functional configuration of the test system.

In the control circuit 100 of the test apparatus 10, the CPU 11 loads a test program stored in the ROM 12 to the RAM 13 and executes the loaded test program to operate as an obtaining unit 101, a backup unit 102, a test execution unit 103, a restoring unit 104, and an initializing unit 105 and execute the test method.

### 5. Operation Sequence of Test System

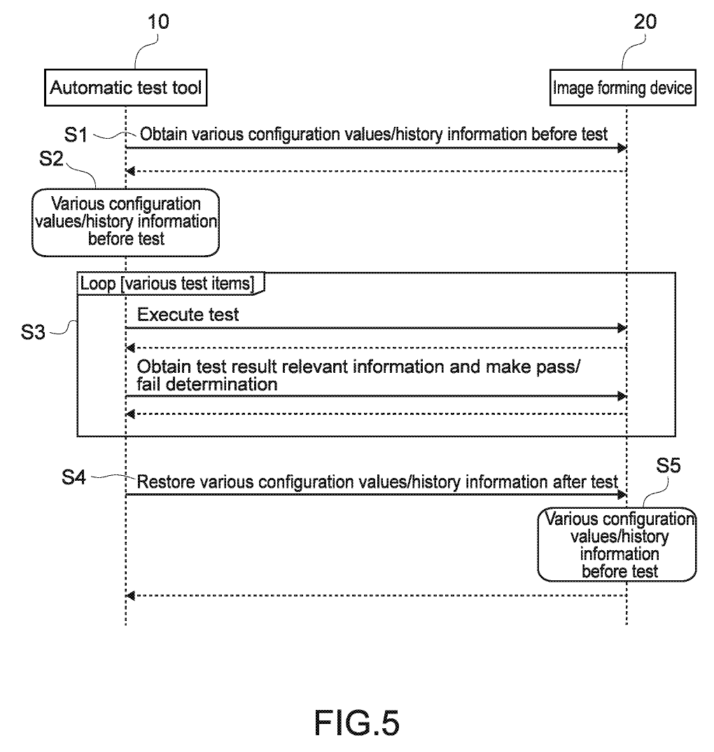

FIG. 5 shows an operation sequence of the test system.

The obtaining unit 101 of the test apparatus 10 obtains configuration values and/or history information (specifically, configuration values and/or history information that is determined with a test item) of the test target electronic device 20 before a test is executed (Step S1). The various configuration values are various configuration values related to the test target electronic device 20 (image forming device). For example, the various configuration values are function ON/OFF configurations, communication configurations, and printing configurations. The various types of history information are job logs, operation logs, various types of counter information, and the like. The backup unit 102 records the obtained configuration values and/or the obtained history information as backup data in a storage device (e.g., the storage device 14 or an external storage device. The same applies hereinafter) (Step S2).

The test execution unit 103 executes a test on the test target electronic device 20 with an automatic test tool, obtains test result relevant information from the test target electronic device 20, and makes a test pass/fail determination (Step S3). The automatic test tool executes a remote device operation instruction from the remote test apparatus 10 (e.g., a PC or server), configuration value reference/change, or the like with respect to the test target electronic device 20 through a communication means (e.g., WSDL, IPP) officially supported by the test target electronic device 20 (image forming device) under development for end users. The test apparatus 10 checks USB logs, configuration values, and the like through another communication means for a test (e.g., NFS, Telnet, prescribe), thereby determining pass or fail with respect to an execution result for each test item.

The restoring unit 104 requests the test target electronic device 20 to restore the backup data (configuration values and/or history information) after the test is executed (Step S4). The test target electronic device 20 restores the backup data (configuration values and/or history information) in accordance with the request (Step S5).

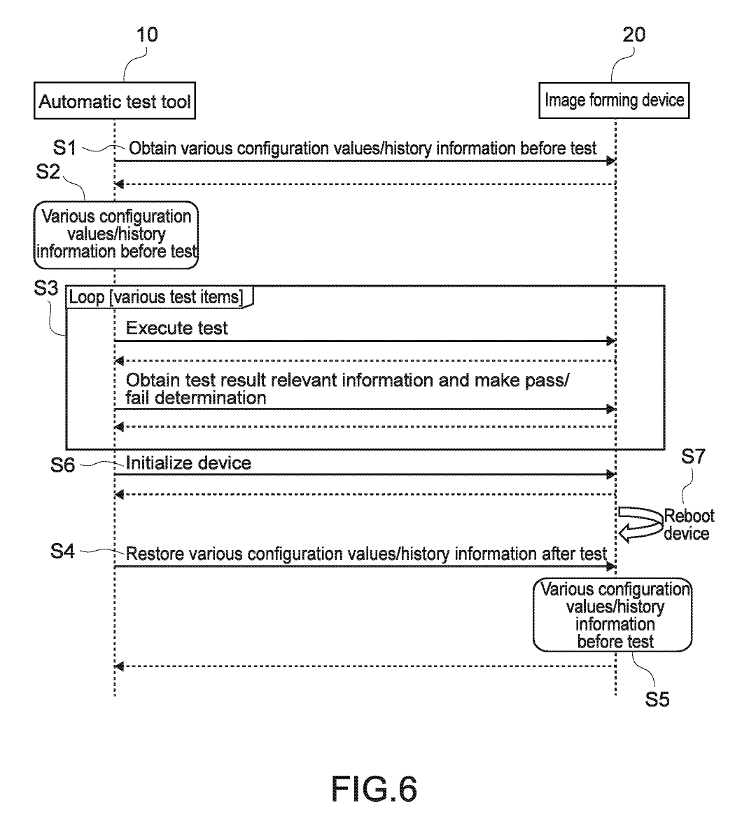

FIG. 6 shows an operation sequence of a test system according to another embodiment.

The initializing unit 105 of the test apparatus 10 requests the test target electronic device 20 to perform initialization after the test is executed (Step S3) and before the restoring (Step S4) (Step S6). The test target electronic device 20 performs initialization in accordance with the request (Step S7). The rest of the operation sequence is similar to that in FIG. 5.

### 6. Conclusion

Only a limited number of prototypes of an electronic device under development (e.g., an image forming device) can be assigned to each department to save the development cost. Therefore, involved developers share the prototypes of the electronic device under development assigned to each department.

When a test is executed on the electronic device under development, events such as changes in configuration values and registration of logs related to jobs caused by the test occur in the prototypes of the tested electronic device under development. In such a case, the configuration values of the prototypes of the electronic device under development that are shared among the developers may be changed to unintended values. This may cause problems, for example, in that the users (developers) cannot thereafter use the prototypes of the electronic device under development as they expect and the users (developers) cannot thereafter conduct tests as they expect due to unintended history registration.

In this regard, in accordance with the first embodiment, before the test with the automatic test tool, back up information of the configuration values and history information of the prototypes (test target electronic devices 20) of the image forming device under development to be tested are obtained. Using each test item with the automatic test tool, the changed configuration values and the affected history information can be determined. After the test is successfully executed with the automatic test tool or during the interruption of the test due to a test fail result, processing of restoring the changed configuration values and history information using the backup information is executed.

By this processing, the changed configuration values and history information with the automatic test tool become similar to the state before the test is executed. The device users (developers) who thereafter use the prototypes (test target electronic devices 20) of the image forming device under development to be tested are prevented from encountering problems for example in that they cannot use the devices as they intend. In a case where multiple tests are executed on the test target electronic device 20, the previous test's impact on the following test can be prevented.

Device initialization may be performed before the configuration values and history information changed are restored using the backup information after the test is successfully executed with the automatic test tool, and then the configuration values and history information changed using the backup information may be restored.

In accordance with the second embodiment, since the changed configuration values and history information become similar to the state before the test is executed, the device users (developers) who thereafter use the prototypes (test target electronic devices 20) of the image forming device under development to be tested are prevented from encountering problems, for example in that they cannot use the devices as they intend.

Although the embodiments and modified examples of the present technology have been described above, the present technology is not limited to those embodiments and various changes can be made without departing from the gist of the present technology as a matter of course.

It should be understood by those skilled in the art that various modifications, combinations, sub-combinations and alterations may occur depending on design requirements and other factors insofar as they are within the scope of the appended claims or the equivalents thereof.

What is claimed is:

1. A test method, comprising:
by a control circuit of a test apparatus executing a test program,
obtaining a configuration value and/or history information of a test target electronic device;
recording the obtained configuration value and/or the obtained history information as backup data in a storage device;
executing a test on the test target electronic device; and
restoring the backup data in the test target electronic device after the test is executed.

2. The test method according to claim 1, further comprising
initializing the test target electronic device after the test is executed and before the restoring.

3. The test method according to claim 1, wherein
the obtaining step includes obtaining a configuration value and/or history information that is determined with a test item.

4. A test apparatus, comprising:
an obtaining unit that obtains a configuration value and/or history information of a test target electronic device;
a backup unit that records the obtained configuration value and/or the obtained history information as backup data in a storage device;
a test execution unit that executes a test on the test target electronic device; and
a restoring unit that restores the backup data in the test target electronic device after the test is executed.

5. A test system, comprising:
a test target electronic device; and
a test apparatus including
an obtaining unit that obtains the configuration value and/or the history information of the test target electronic device,
a backup unit that records the obtained configuration value and/or the obtained history information as backup data in a storage device,
a test execution unit that executes a test on the test target electronic device, and
a restoring unit that restores the backup data in the test target electronic device after the test is executed.
